(19) United States
(12) Patent Application Publication
(10) Pub. No.: US 2015/0323566 A1
(43) Pub. Date: Nov. 12, 2015

(54) CONVERSION CARD FOR USE WITH PROBE CARD

(71) Applicant: TING-JUE JAN, TAOYUAN CITY (TW)

(72) Inventor: TING-JUE JAN, TAOYUAN CITY (TW)

(21) Appl. No.: 14/702,764

(22) Filed: May 4, 2015

(30) Foreign Application Priority Data
May 9, 2014 (TW) 1031166505

(51) Int. Cl. G01R 1/067; H02M 7/44; G01R 1/073

(52) U.S. Cl. CPC G01R 1/06766; G01R 1/07342; H02M 7/44

(57) ABSTRACT

A conversion card is provided for use with a probe card and includes a board and first transmission units, second transmission units, and a DC/AC conversion circuit formed on the board. The first transmission units are electrically connected to test instruments. The second transmission units are electrically connected to a POGO tower. The DC/AC conversion circuit is electrically connected to the first and second transmission units. The first transmission unit is fed with an AC signal that is transmitted through the DC/AC conversion circuit, the second transmission units, and the POGO tower to the probe card. Through the use of AC circuit and transmission line theory, in combination with AC signal test instruments, an AC based process can be used to conduct error analysis tests and improvement of the probe card to prevent mistakenly determine the error rate of the probe card.

### (a) TECHNICAL FIELD OF THE INVENTION

The present invention relates generally to a conversion card, and more particularly to a conversion card for use with a probe card.

### (b) DESCRIPTION OF THE PRIOR ART

It has long been a common practice to verify the operability of a direct current (DC) probe card before a wafer acceptance test is conducted. This is because the probe card plays an important role in finally determining if the functionality of integrated circuits (ICs) is normal in the final test stage before the wafer is diced. After the functionality of the ICs has been tested and is determined to be normal, the ICs are diced and packaged, prepared for the subsequent bin-based sorting. It is manifest that the efficiency and quality of the subsequent product shipping will be surely affected when the error rate of the probe card gets high. However, the functions of an IC tests is getting increased and the number of pins of a probe card involved is also increased up to as many as tens of thousands of pins, costing several million dollars. Thus, if a probe card is determined to be of a high error rate, then the pins must be cleaned or even the card itself be replaced. These operations are extremely time-consuming and costly. In case of rush supply of product to the customers, wafer foundries and test may take a simple solution of directly and repeatedly changing potential malfunctioning cards until a normally operable card is selected. The cost of these replaced cards must be taken by the wafer foundries and the test provider themselves. Consequently, there is always a high stock of the probe card, which may be of a cost of up to tens of millions or even hundreds of millions of dollars, leading to a great increase of cost.

The semiconductor industry has long relied on DC test methods to test the DC probe cards and the progress and improvement of such methods have been in a bottleneck condition. The present invention aims to provide a solution that is based on fault analysis and improvement of a DC probe card by using an alternating current (AC) process.

### SUMMARY OF THE INVENTION

An object of the preset invention is to provide a conversion card for use with a probe card that comprises a first transmission unit for transmission of an AC signal and feeds the AC signal through a DC/AC conversion circuit and a second transmission unit to the probe card, so that AC may be applied, in combination with the use of AC signal instrument, to error analysis test and improvement of a DC probe card through an AC circuit and transmission line theory.

To achieve the above object, the present invention provides a conversion card comprises a board, at least one first transmission unit, at least one second transmission unit, and a DC/AC conversion circuit, wherein the first transmission unit is formed on the board and the first transmission unit is electrically connected to a test instrument for transmission of an AC signal; the second transmission unit is formed on the board and the second transmission unit is electrically connected to a POGO tower; and the DC/AC conversion circuit is formed on the board and the DC/AC conversion circuit is electrically connected to the first transmission unit and the second transmission unit.

As such, the first transmission unit is fed with an AC signal and the AC signal is transmitted through the DC/AC conversion circuit, the second transmission unit, and the POGO tower to a probe card. Through the use of AC circuit and transmission line theory, in combination with AC signal test instruments, such as a logic analyzer, an oscilloscope, a time domain reflectometer, a frequency domain network analyzer, an bit error rate tester, and an eye-diagram analyzer, an AC based process can be used to conduct error analysis tests and improvement of the probe card to prevent mistakenly determine the error rate of the probe card so as to reduce the frequency of card change and pin cleaning of the probe card and also help reducing stock of probe cards.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic view showing the present invention.

FIG. 2 is a top plan view, in an enlarged form, showing a portion of the present invention.

FIG. 3 is an exploded view illustrating an example of test conducted with the present invention.

FIG. 4 is a cross-sectional view illustrating an example of test conducted with the present invention.

FIG. 5 is a block diagram of the present invention.

FIG. 6 is a schematic view illustrating an example of test conducted with the present invention in combination with a logic analyzer and a digital signal generator.

FIG. 7 is a diagram illustrating the result of test of FIG. 6.

FIG. 8 is a schematic view illustrating an example of test conducted with the present invention in combination with a logic analyzer, an oscilloscope, and a digital signal generator.

FIG. 9 is a diagram illustrating the result of test of FIG. 8.

FIG. 10 is a schematic view illustrating an example of test conducted with the present invention in combination with a time domain reflectometer.

FIG. 11 is a diagram illustrating the result of test of FIG. 10.

FIG. 12 is a schematic view illustrating an example of test conducted with the present invention in combination with a frequency domain network analyzer.

FIG. 13 is a diagram illustrating the result of test of FIG. 12.

FIG. 14 is a schematic view illustrating an example of test conducted with the present invention in combination with an eye-diagram analyzer and a bit error rate tester.

FIG. 15 is a diagram illustrating the result of test of FIG. 14.

FIG. 16 is a schematic view illustrating an example of test conducted with the present invention in combination with an eye-diagram analyzer and bit error rate tester combined device.

FIG. 17 is a flow chart illustrating a process of test according to the present invention.

### DETAILED DESCRIPTION OF THE PREFERRED EMBODIMENTS

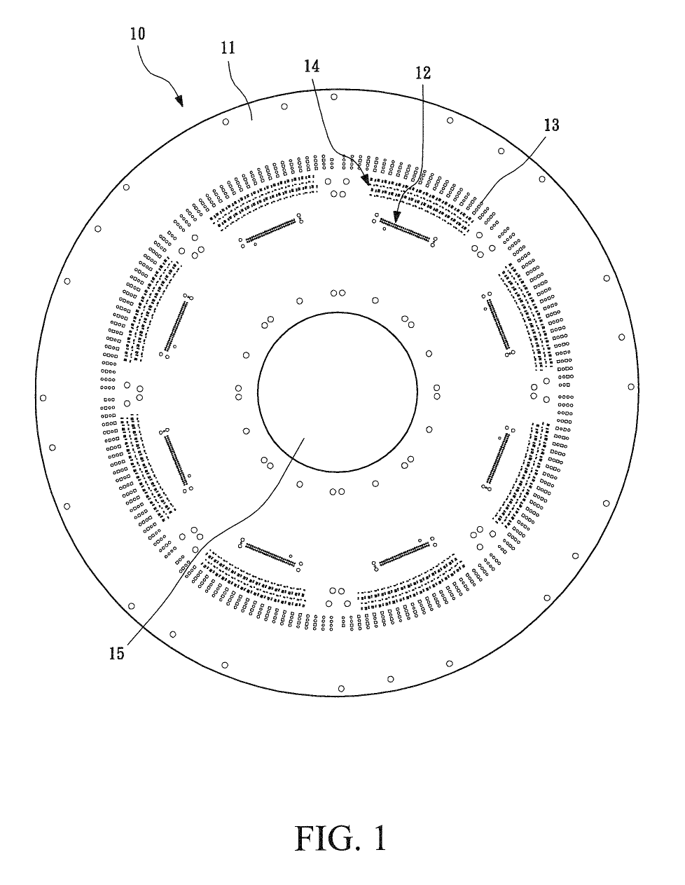

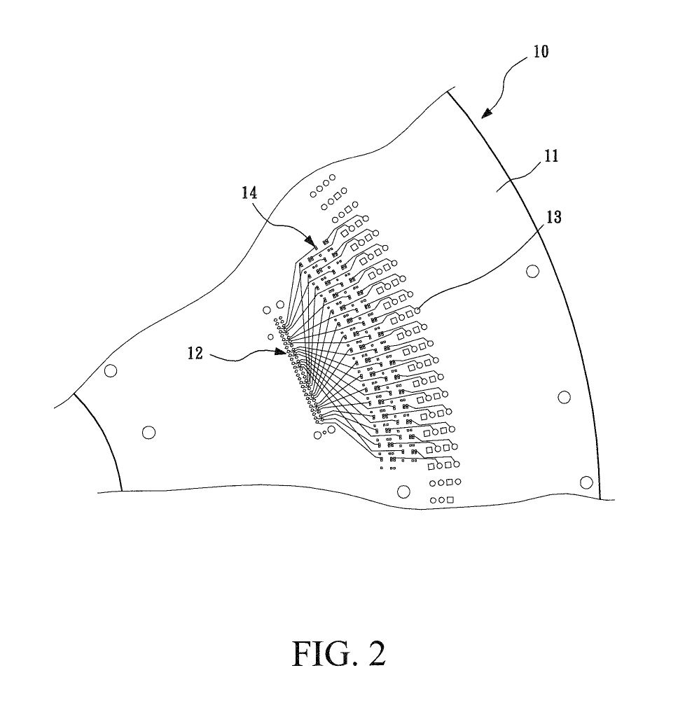

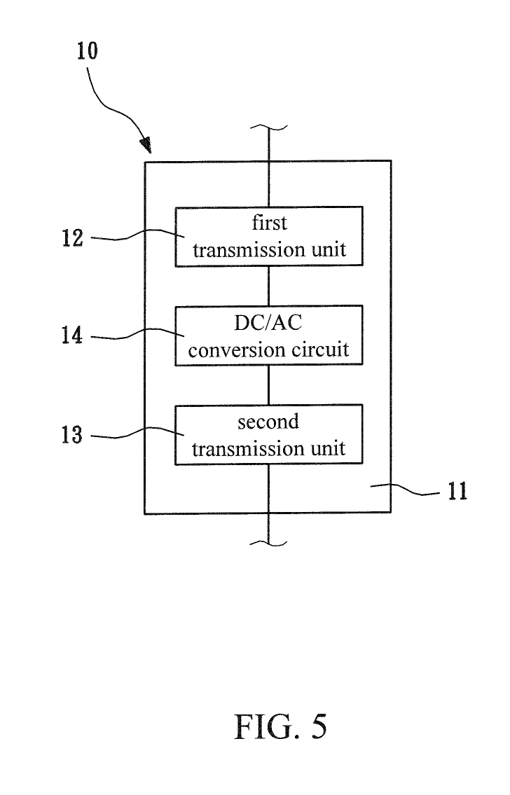

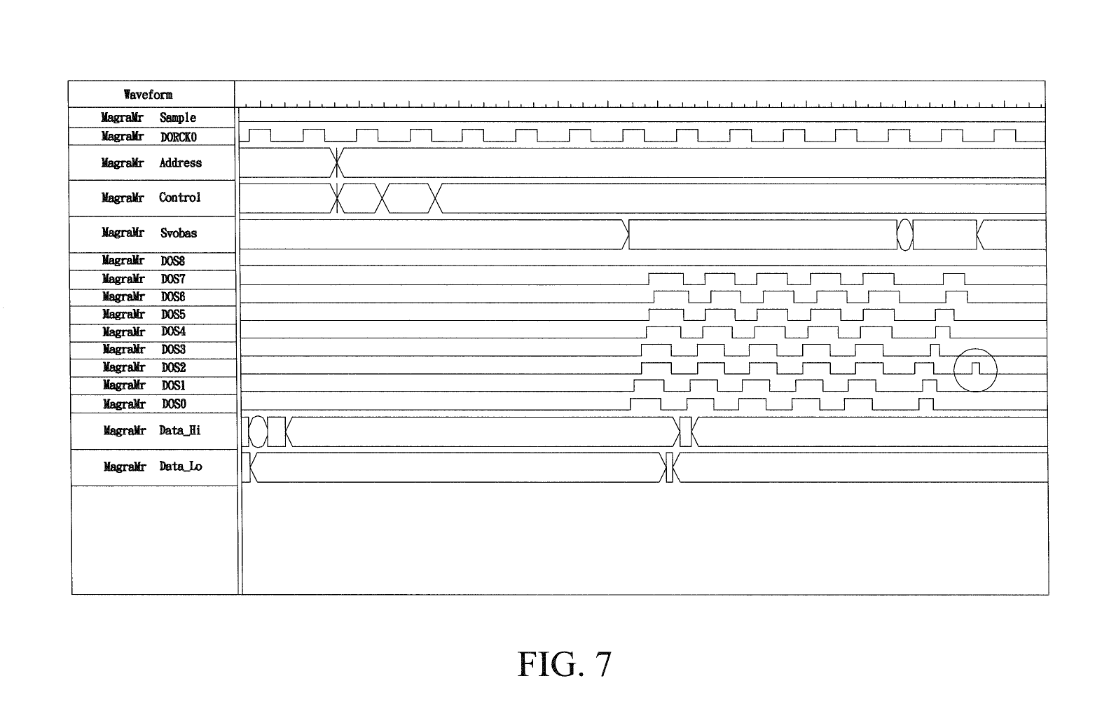

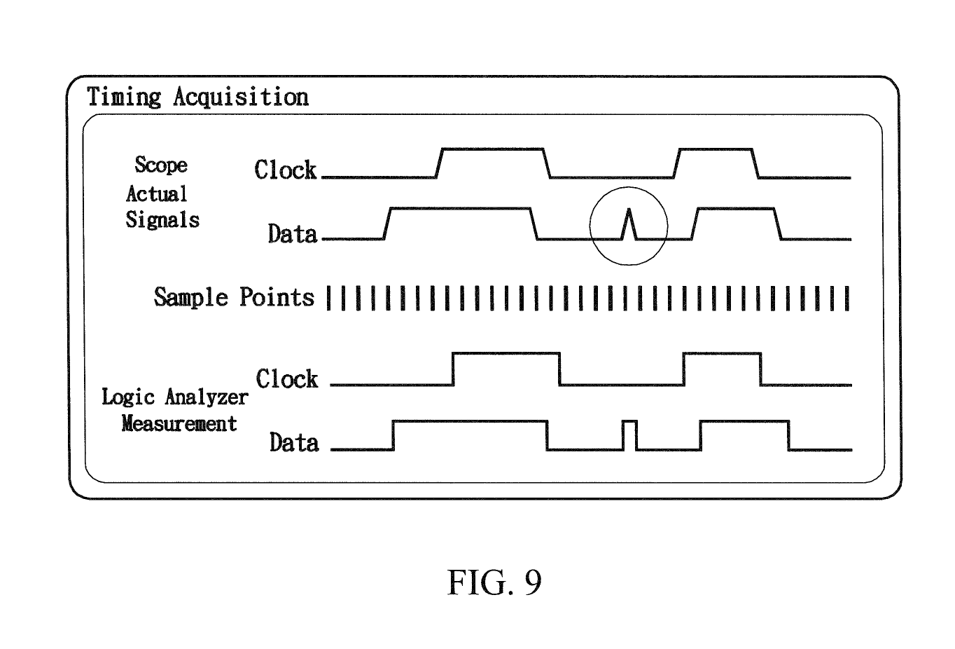

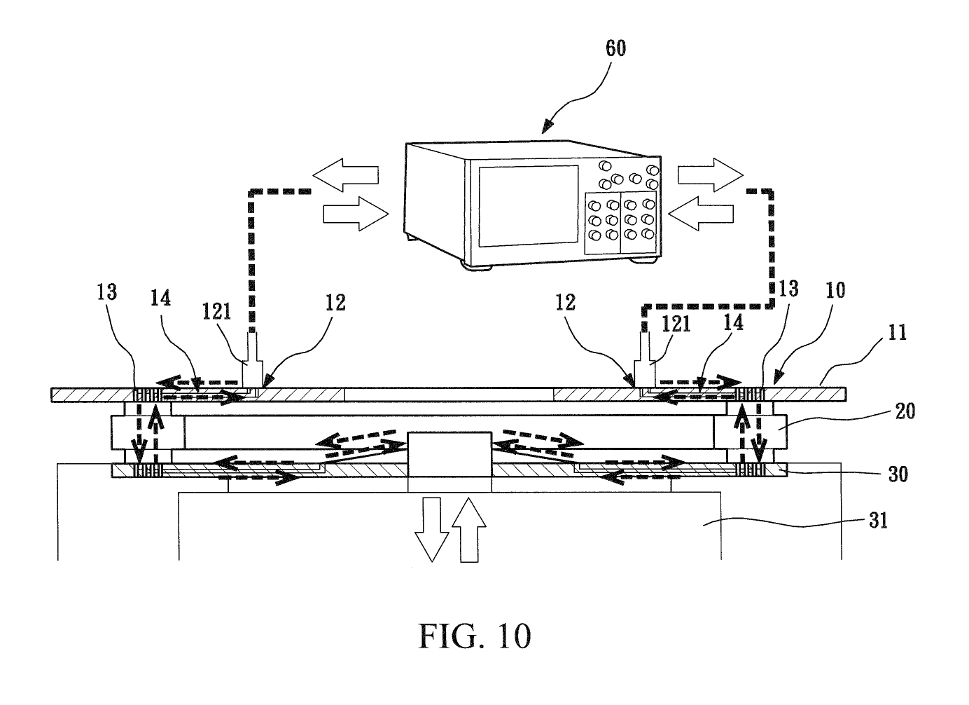

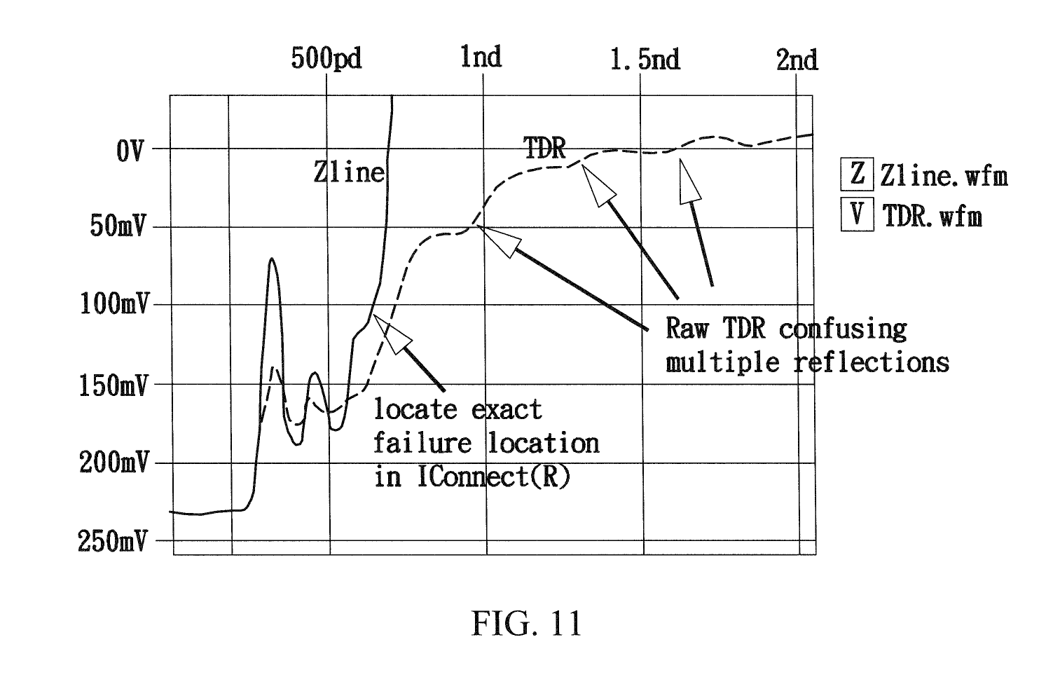

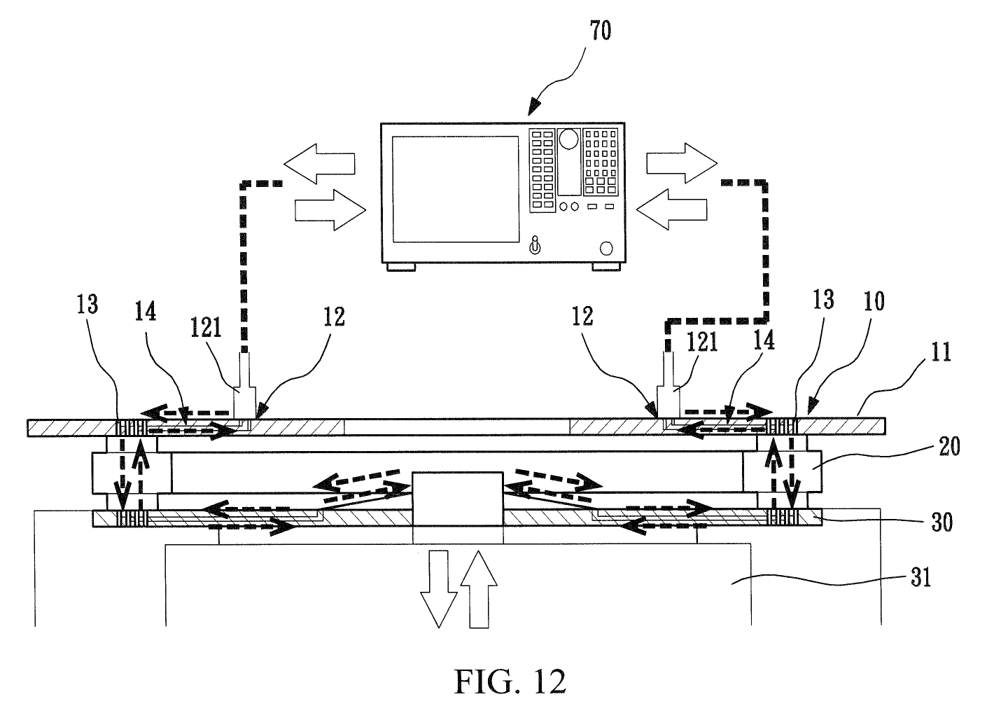

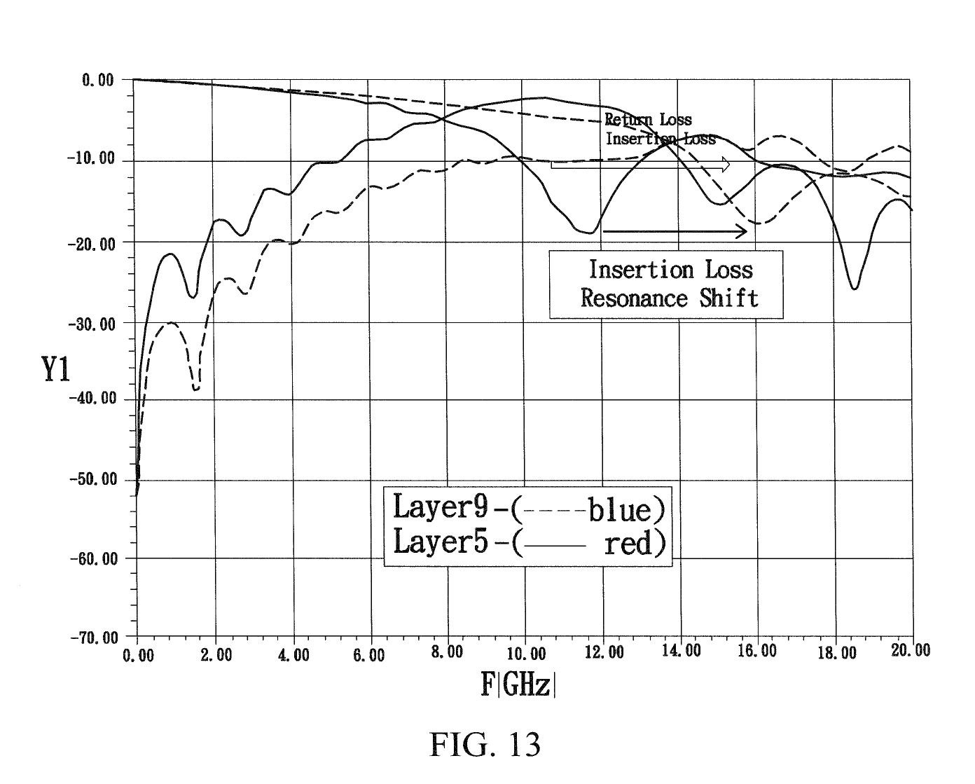

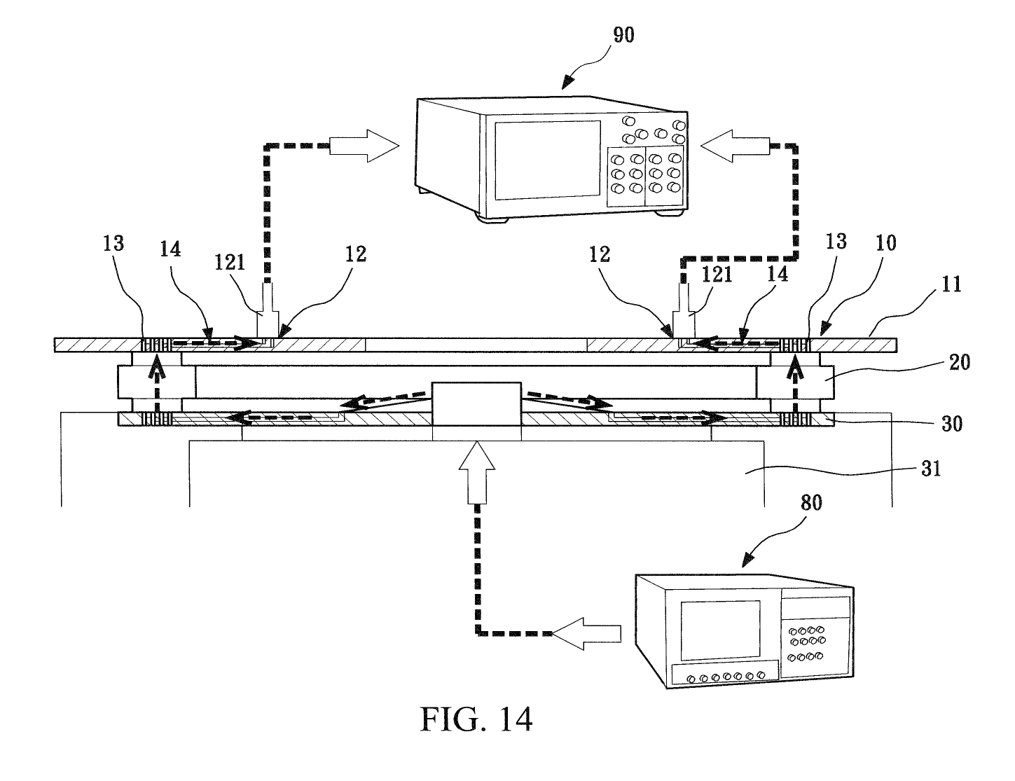

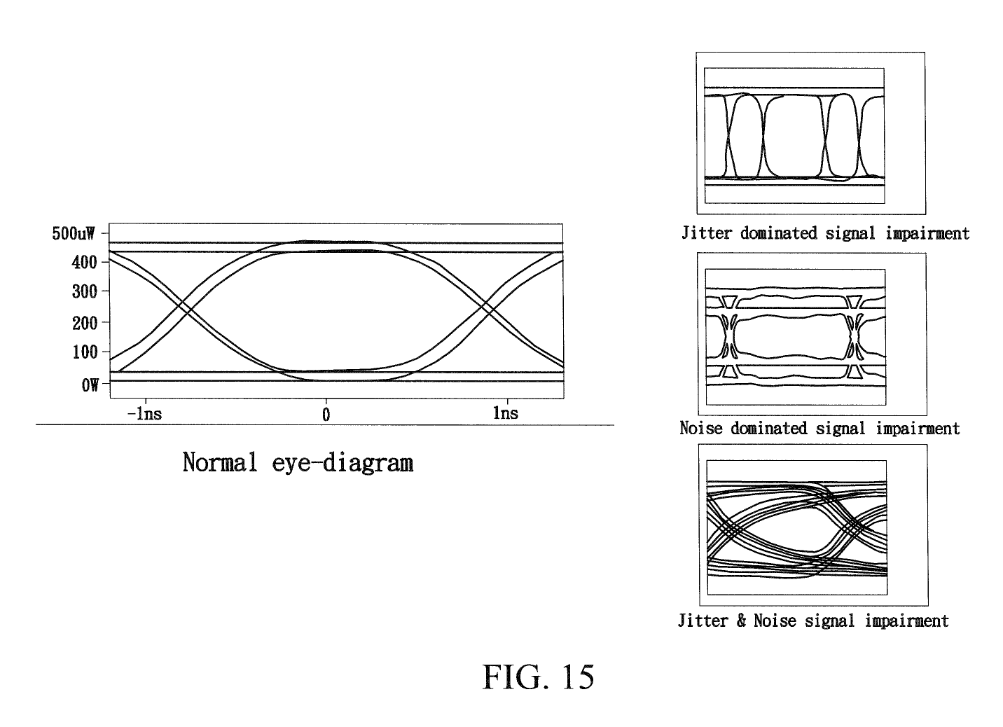

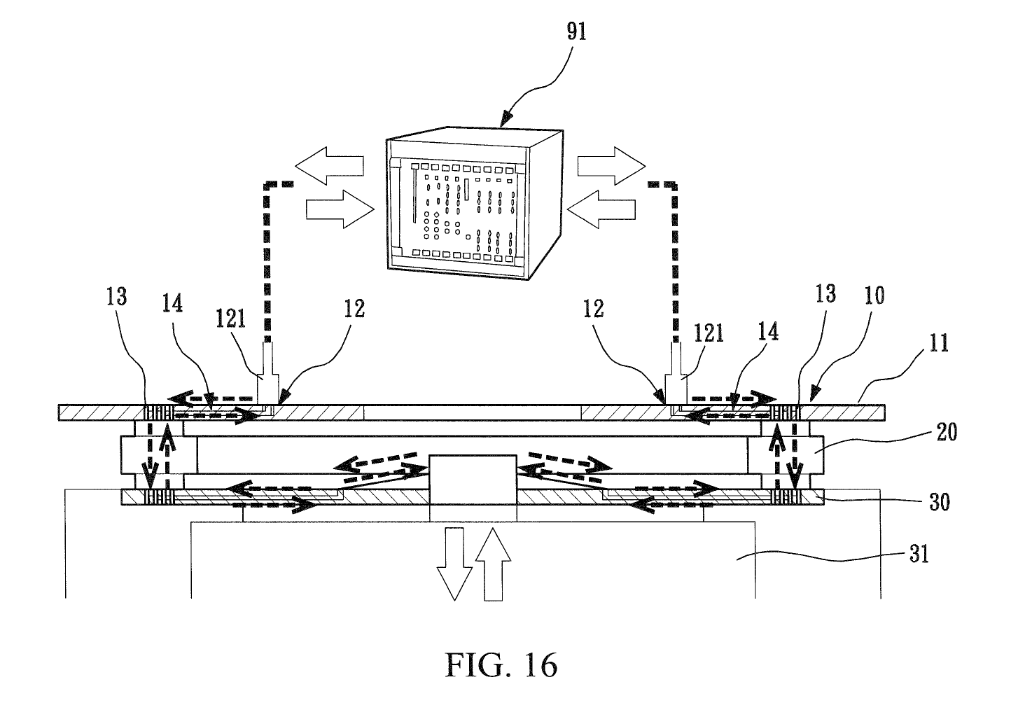

Referring to FIGS. 1-16, the present invention provides a conversion card 10 for use with a probe card, which comprise a board 11, a plurality of first transmission units 12, a plurality of second transmission units 13, and a DC/AC conversion circuit 14.

In an embodiment, the board 11 comprises an opening 15 formed therethrough for reducing weight and the amount of material used so as to lower down the manufacturing cost.

The first transmission units 12 are mounted on the board 11. The first transmission units 12 are electrically connectable to predetermined test instruments for transmission of AC signals. In the embodiment, the first transmission units 12 are arranged to be connectable with connection cables 121 of the test instruments. As illustrated, eight first transmission units 12 are provided and evenly arranged on the board 11, so that a plurality of connection cables 121 is allowed to simultaneously and electrically connect to the plurality of first transmission units 12. As such, a test instrument may use one connection cable 121 to alternately connect to the first transmission units 12 of different areas to conducted sectionized tests on the probe card 30; or alternatively, a test instrument or test instruments may use a plurality of connection cables 121 to respectively connect to the first transmission units 12 of different areas to conduct simultaneous sectionized tests on the probe card 30.

In an embodiment, the first transmission units 12 comprise a plurality of electrically connection holes or receptacle arranged in a zone.

The second transmission units 13 are mounted on the board 11. The second transmission units 13 are electrically connectable to a POGO tower 20.

In an embodiment, the first transmission units 12 comprise electrical connection holes or receptacles. In the embodiment, the POGO tower 20 has a top on which a plurality of pins is provided for insertion into the second transmission units 13.

The DC/AC conversion circuit 14 is formed on the board 11. The DC/AC conversion circuit 14 is electrically connected to the first transmission units 12 and the second transmission units 13.

In the configuration of an embodiment, the board 11, the first transmission units 12, the second transmission units 13, and the DC/AC conversion circuit 14 are integrally formed as a printed circuit board (PCB); or alternatively, the board 11, the first transmission units 12, the second transmission units 13, and the DC/AC conversion circuit 14 are bond to each other as a unitary structure.

The AC signals are fed in through the first transmission unit 12 and the AC signals are then transmitted through the DC/AC conversion circuit 14, the second transmission units 13, and the POGO tower 20 to a probe card 30. Through the use of AC circuit and transmission line theory, in combination with AC signal test instruments, such as a logic analyzer 40, an oscilloscope 50, a time domain reflectometer 60, a frequency domain network analyzer 70, an bit error rate tester 80, and an eye-diagram analyzer 90, an AC based process can be used to conduct error analysis tests and improvement of the probe card 30 to prevent mistakenly determine the error rate of the probe card so as to reduce the frequency of card change and pin cleaning of the probe card and also help reducing stock of probe cards.

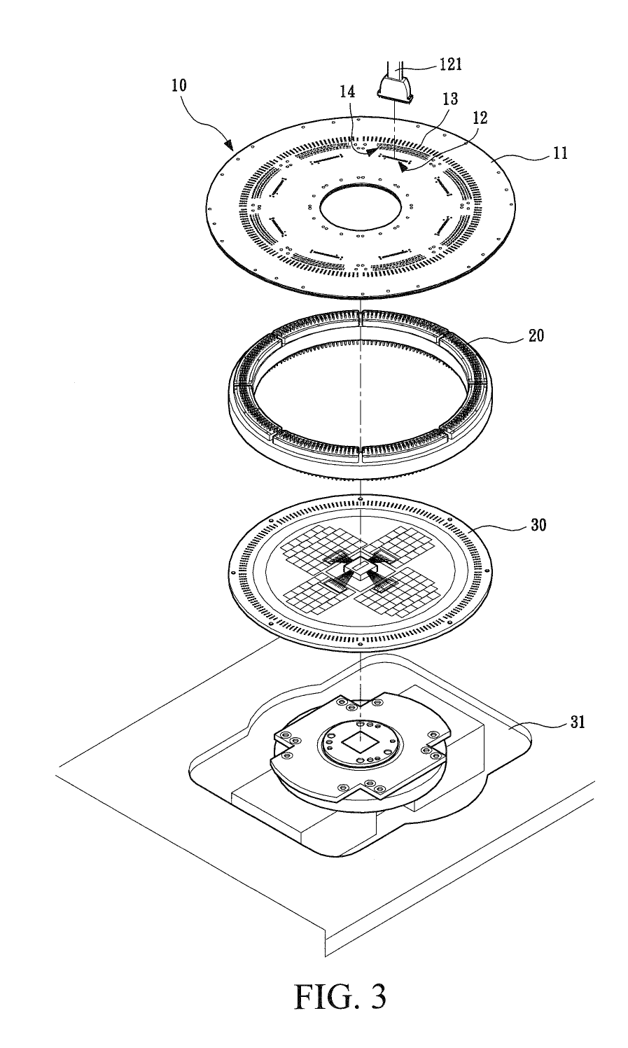

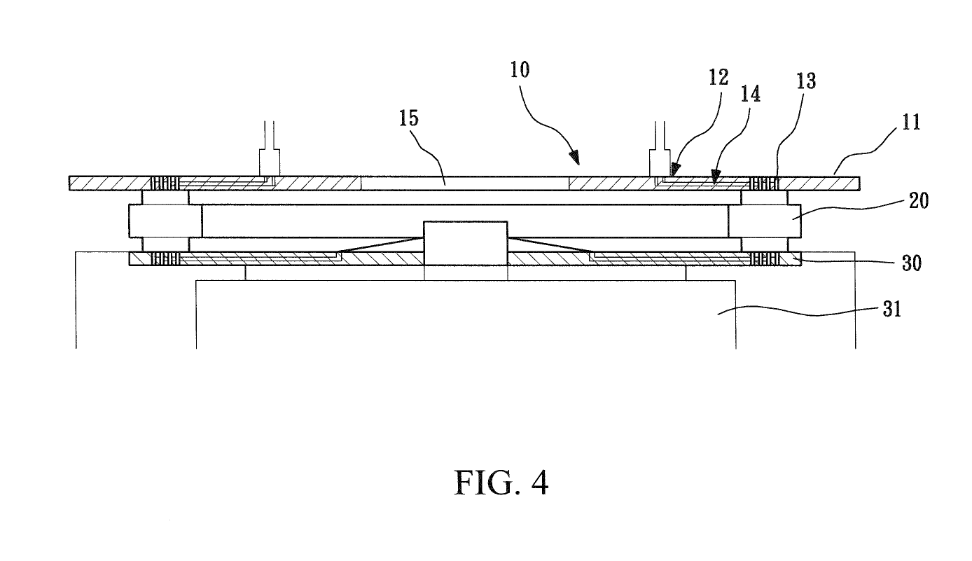

Referring to FIGS. 3 and 4, in a configuration for test, the present invention is set on the POGO tower 20 and the POGO tower 20 is in turn set on the probe card 30, and the probe card 30 is in turn set on test equipment 31.

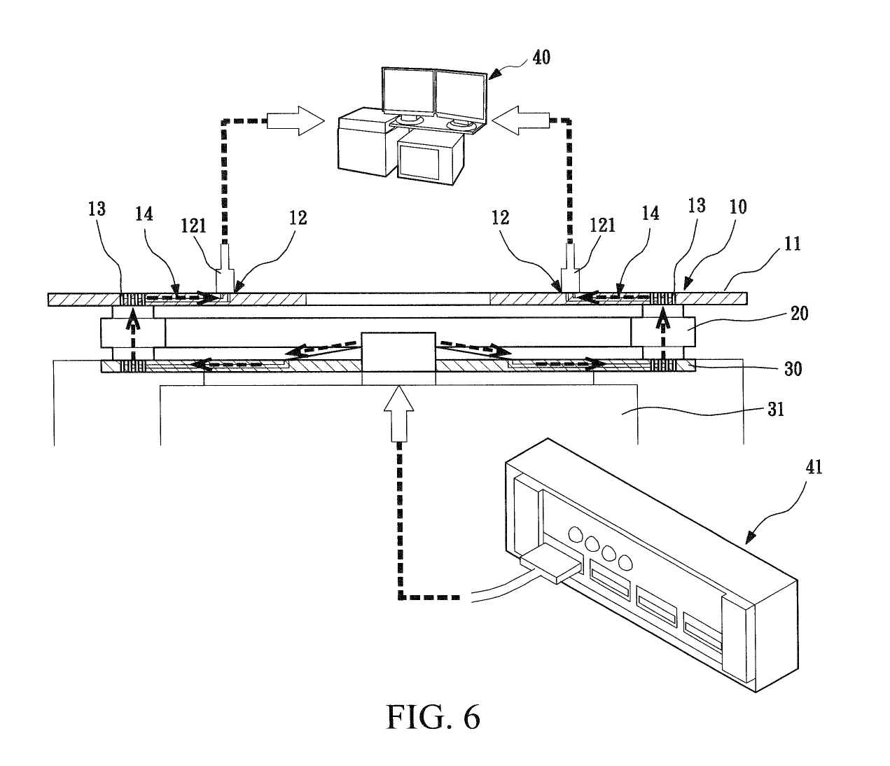

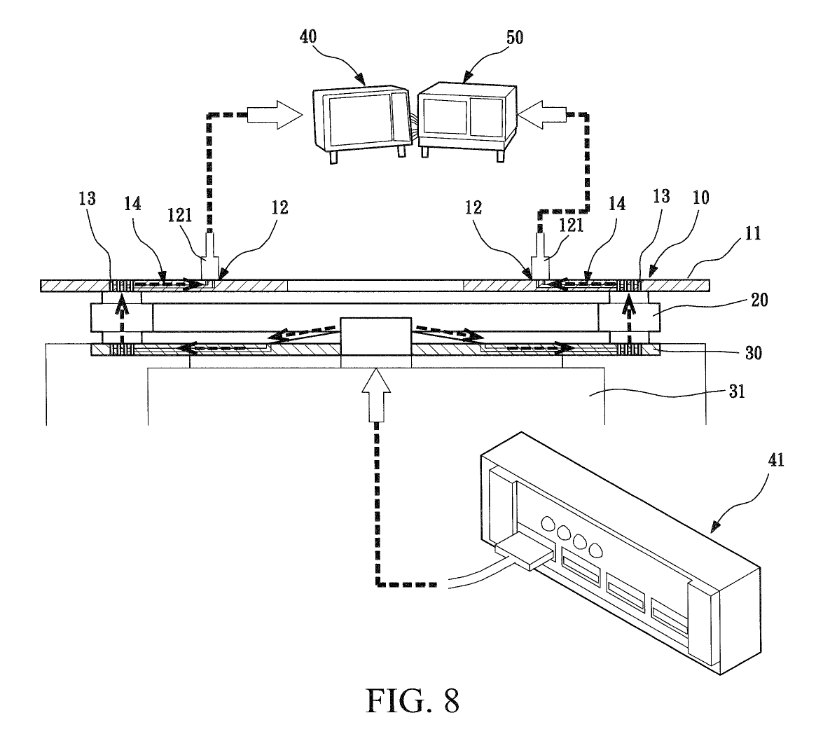

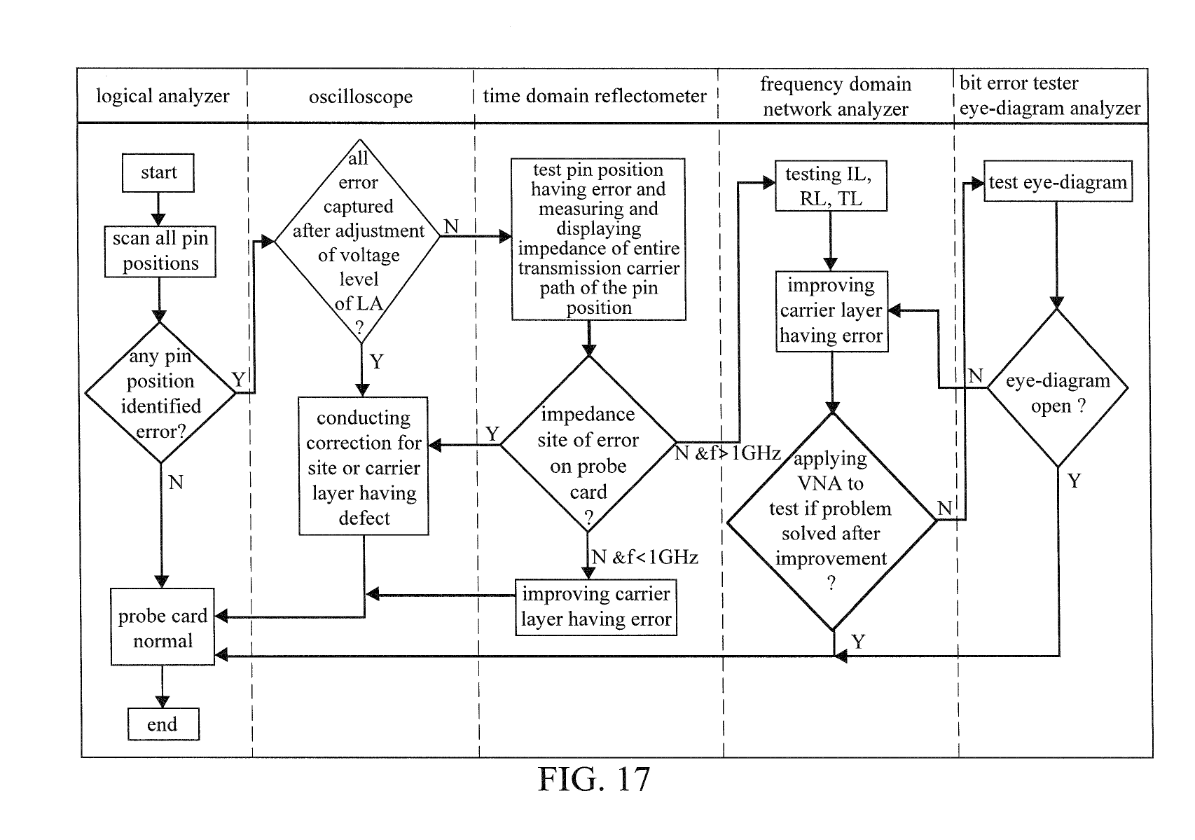

Referring to FIGS. 6-17, in an example of proceeding with a test according to the present invention, the first transmission units 12 of the board 11 are electrically connected, through the connection cable 121, to AC signals test instruments, such as a logic analyzer 40, an oscilloscope 50, a time domain reflectometer 60, a frequency domain network analyzer 70, an bit error rate tester 80, an eye-diagram analyzer 90, and a bit error rate tester and eye-diagram analyzer combined device 91. Further, a digital signal generator 41 (as shown in FIG. 8) is used in combination with the logic analyzer 40 or in combination with both the logic analyzer 40 and the oscilloscope 50 for being in electrical connection with the probe card 30. Thus, the above AC signal test instruments are operable in accordance with predetermined test procedures to conduct error analysis test and improvement of the probe card 30, and the result of the test and improvement can be displayed on the AC signal test instruments.

Further, it is also feasible to conduct error analysis test and improvement of the probe card 30 by selecting and operating only some, not all, of the AC signal test instruments.

The conventional process of direct current based tests can only work with a predetermined level of voltage/current and is generally carried out by feeding a voltage and measuring a current or alternatively feeding a current and measuring a voltage. This surely leads to an undesired consequence that a signal that causes a problem but is not within the predetermined range or at the predetermined level will be simply neglected for being not detected. This also causes a mistaken determination regarding the operability of the probe card 30. On the other hand, if an AC based process is adopted, since the level is variable in a periodic manner, this, when used in combination with proper adjustment of different levels of the logic analyzer 40, it is more likely to identify a key error signal that is generally concealed in the way of applying a standard level of direct current so as to allow for ready identification of which of the pins that causes the error. Based on this, improvement can be made in respect of such a pin. Further, the logic analyzer 40 is capable of operating on more than 2,000 pins to make correct determination among these pins. Thus, when the total number of pins of the probe card 30 exceeds ten thousands, sectionized tests can be adopted in order to complete the tests of all the pins in a most efficient manner. A conventional probe card analyzer that is currently available is capable of testing a pin with an average time period of around 2 seconds and it would require twenty thousands of seconds for testing ten thousands of pins. A comparison is given in the following table to distinguish the differences therebetween.

| | | | time for testing | time for testing |
|---|---|---|---|---|
| | time for | number of pins | 10,000 pins, | 20,000 pins, |
| | testing | allowed for | including | including |
| | one pin | being tested | overhead time | overhead time |
| | (sec.) | simultaneously | (sec.) | (sec.) |
| Conventional | 2 | 1 | 21000 (about | 43000 (about |
| Probe Card | | | 6 hrs.) | 12 hrs.) |
| Analyzer | | | | |
| The Present | 2 | 2000 | 20 | 60 |
| Invention | | | | |

Since the entirety of the test system is comprised of four to five layers of different carriers between the probe card and the carrier board and each of the carriers has different impedance characteristics and impedance matching issue, each of the pins exhibits different impedance characteristic (even for the same process). If a time domain reflectometer 60 is used to analyze and identify the pin that causes an error, since the output of this instrument is a step wave having an extremely high frequency and the rising time is around 7-12 pico seconds and thus, resolution may be in the order of nano meter. Since the current design and application of ICs are in the level of GHz (such as DDR3, HDMI, and PCI-e) and products need to be thin, light, and compact while providing powerful functions, ICs are getting increasingly smaller and having increased functions. Accordingly, the internal circuits of ICs are getting complicated and the transmission line effect is getting more apparent. In other words, a small defect of the manufacturing process may cause different inductive or parasitic capacitance, inductance, resistance for different frequencies (which are collectively referred to inductive circuit), so that the original behavior characteristics are all affected by the inductive circuit so formed. This is generally not identifiable in the direct current world. The present invention uses the step wave of a time domain reflectometer 60 to achieve successful analysis of the site where the inductive circuit is generated and may determined the characteristics of the inductive circuit occurring in such a site so that improvement can be made based on the site. Since the resolution is at a level of nanometer, it is possible to determine which one of the carriers in which the error occurs, and not simply concluded the probe card is broken.

When a digital signal flows in an IC, how to correctly output or input a desired digital signal at a proper time is related to if this IC can achieve desired functions in an actual product. As discussed previously, the current applications are all in the level of GHz, the accuracy of clock and precise control of input and output of signal are very important. Clock signals are commonly interfered with by jitters and system and noises generated by various high frequencies, the bit error rate tester 80 and the eye-diagram analyzer 90 must be employed to realize the quality of signal transmission and to analyze the factors that causes jitter (such as total jitter (TJ), periodic jitter (PJ), and duty-cycle jitter (DCD)) or noise (such as random noise (RN), deterministic noise (DN), and data dependent noise (DDN)).

As stated previously, all the current applications are in the GHz level, namely the radio frequency (RF) level, so that an RF network analyzer must be used to the frequency domain behavior of the carrier system under the radio frequency, such as insertion loss, return loss, and transitions loss. This, when used in combination with the previous conditions, allows for realization of the behavior of each level of carriers in time domain and frequency domain, so that improvement may be made through different means and measures.

From the above, it is understood that the present invention provides an arrangement of a board, first transmission units, second transmission units, and a DC/AC conversion circuit to have the structure of testing a probe card integrated and united together and AC and transmission line theory are applied to all key parameters at one process and the factors that causes errors. This not only helps reduce high inventory rate of probe cards, but also help remove more errors for facilitating subsequent functional tests thereby increasing the speed of product overcoming the bottleneck of DC based probe card testing and allowing for identification of characteristics and errors of not just the probe card, but all the levels of the testing, such as load board, load boar and POGO tower, probe head and needle, so that a true solution can be obtained for the level where the problems occur and thus, there is no need to just repeatedly change the probe card and cleaning the card.

It will be understood that each of the elements described above, or two or more together may also find a useful application in other types of methods differing from the type described above.

I claim:

1. A conversion card for use with a probe card, comprising:
a board;
at least one first transmission unit, which is formed on the board, the first transmission unit being eclectically connectable to a test instrument for transmission of an alternating current (AC) signal;
at least one second transmission unit, which is formed on the board, the second transmission unit being electrically connectable to a POGO tower; and
a DC/AC conversion circuit, which is formed on the board, the DC/AC conversion circuit being electrically connected to the first transmission unit and the second transmission unit.

2. The conversion card for use with the probe card according to claim 1, wherein the board comprises an opening formed therethrough.

3. The conversion card for use with the probe card according to claim 1, wherein the first transmission unit comprises a plurality of electrical connection holes arranged in a zone.

4. The conversion card for use with the probe card according to claim 1, wherein the second transmission unit comprises an electrical connection hole.

5. The conversion card for use with the probe card according to claim 1, wherein the board, the first transmission unit, the second transmission unit, and the DC/AC conversion circuit are integrally formed together in the form of a printed circuit board.

6. The conversion card for use with the probe card according to claim 1, wherein the board, the first transmission unit, the second transmission unit, and the DC/AC conversion circuit are bonded together as a unitary structure.
